(19) United States
(12) Patent Application Publication
(10) Pub. No.: US 2003/0096465 A1
(43) Pub. Date: May 22, 2003

(54) Hard mask trimming with thin hard mask layer and top protection layer

(75) Inventors: Cheng-Ku Chen, Hsinchu (TW); Fang-Cheng Chen, Hsin-Chu (TW); Hun-Jan Tao, Hsinchu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 09/996,864

(22) Filed: Nov. 19, 2001

(51) Int. Cl. H01L 21/336

(52) U.S. Cl. 438/197

(57) ABSTRACT

Hard mask trimming with a thin hard mask layer and a top protection layer is disclosed. During fabrication of a semiconductor device, the device has a primary layer, a lower layer, and an upper layer. The primary layer, which may be a polysilicon layer, has a critical dimension specification. The lower layer is over the polysilicon layer, and is subsequently hard mask trimmed to satisfy the critical dimension specification of the primary layer. The upper layer is over the lower layer, and has a high-etching selectivity as compared to the lower layer. The upper layer substantially prevents thickness loss of the lower layer during hard mask trimming. Each of the upper layer and the lower layer may be Si₃N₄, SiON, or SiO₂. Additionally, the upper layer may be polysilicon.

### FIELD OF THE INVENTION

This invention relates generally to semiconductor device fabrication, and more particularly to fabrication of such devices using a hard mask trimming process.

### BACKGROUND OF THE INVENTION

Since the invention of the integrated circuit (IC), semiconductor chip features have become exponentially smaller and the number of transistors per device exponentially larger. Advanced IC's with hundreds of millions of transistors at feature sizes of 0.25 micron, 0.18 micron, and less are becoming routine. Improvement in overlay tolerances in photolithography, and the introduction of new light sources with progressively shorter wavelengths, have allowed optical steppers to significantly reduce the resolution limit for semiconductor fabrication far beyond one micron. To continue to make chip features smaller, and increase the transistor density of semiconductor devices, IC's have begun to be manufactured that have features smaller than the lithographic wavelength.

One feature that has particularly decreased in size is the transistor gate. A gate is the control electrode in a field-effect transistor (FET). A voltage applied to the gate regulates the conducting properties of the semiconductor channel region, which is usually located directly beneath the gate. In a MESFET (metal semiconductor field effect transistor), the gate is in intimate contact with the semiconductor. In a MOSFET (metal oxide semiconductor field effect transistor), it is separated from the semiconductor by a thin oxide, typically 100-1000 angstroms thick.

Most current semiconductor fabrication processes can achieve gates that have a width no smaller than 0.05 micron. These processes may use photoresist dry trimming to achieve so-called narrow gates of this width. Photoresist trimming is the process by which photoresist that has been applied to a semiconductor substrate is exposed to an exposure light source according to a pattern, developed to remove the part of the photoresist that was exposed, and finally further trimmed to remove even more of the photoresist. The part of the photoresist that was not exposed because it was beneath under opaque regions of the pattern during exposure usually remains. The polysilicon or other material deposited on the substrate below the photoresist is then trimmed to form gates and other features within the polysilicon.

Patterning and trimming can be dry etching or wet etching processes. Wet etching refers to the use of wet chemical processing to selectively remove the material from the wafer. The chemicals are placed on the surface of the wafer, or the wafer itself is submerged in the chemicals. Dry etching refers to the use of plasma stripping, using a gas such as oxygen (O₂), C₂F₆ and O₂, or another gas. Whereas wet etching is a low-temperature process, dry etching is typically a high-temperature process.

However, photoresist trimming can only trim about 0.05 micron from the width of a photoresist layer, limiting how narrow the width of a gate can be fabricated. Where the width of the photoresist layer is initially 0.11 micron, for instance, this means that the narrowest the CD width of a gate that can be fabricated is 0.06 micron. This is problematic, because new semiconductor device designs may require a gate with a much smaller width. For example, some new semiconductor device designs may require a gate having a width of 0.035 micron. Furthermore, even achieving photoresist trimming of about 0.05 micron is difficult, because local pattern density and other effects may cause defects in the semiconductor devices resulting from such large-scale trimming.

To trim more than about 0.05 from the width of a photoresist layer, hard mask trimming can be utilized. Hard mask trimming involves the use of a hard mask layer underneath the photoresist. Single layer hard mask trimming, however, comes with its own disadvantages. During lateral CD trimming, for instance, a significant amount of the thickness of the hard mask layer can be lost. Where such CD trimming is accomplished on a large scale, it requires the use of a relatively thick single hard mask layer, to compensate for the thickness of the hard mask layer that will be lost. However, using a single thick hard mask layer also is disadvantageous, because it can narrow the process window for photolithography and under-layer etching, especially for single trench isolation (STI) etching. A process window, such as an exposure-defocus (ED) window, maps the ranges within which acceptable lithographic quality occurs. The process window for a given feature shows the ranges of exposure dose and depth of focus (DOF) that permit acceptable lithographic quality.

For example, FIG. 1 shows a graph 100 of a typical ED process window for a given semiconductor pattern feature. The y-axis 102 indicates exposure dose of the light source being used, whereas the x-axis 104 indicates DOF. The line 106 maps exposure dose versus DOF at one end of the tolerance range for the critical dimension (CD) of the pattern feature, whereas the line 108 maps exposure dose versus DOF at the other end of the tolerance range for the CD of the feature. The area 110 enclosed by the lines 106 and 108 is the ED process window for the pattern feature, indicating the ranges of both DOF and exposure dose that permit acceptable lithographic quality of the feature. Any DOF-exposure dose pair that maps within the area 110 permits acceptable lithographic quality of the pattern feature. As indicated by the area 110, the process window is typically indicated as a rectangle, but this is not always the case, nor is it necessary.

Therefore, there is a need for hard mask trimming that overcomes the disadvantages associated with hard mask trimming as found in the prior art. Specifically, there is a need for hard mask trimming that does not require a thick hard mask layer. That is, there is a need for hard mask trimming that does not narrow the process window for photolithography and other semiconductor processes. For these and other reasons, there is a need for the present invention.

### SUMMARY OF THE INVENTION

The invention relates to hard mask trimming with a thin hard mask layer and a top protection layer. During fabrication of a semiconductor device, the device has a primary layer, a lower layer, and an upper layer. The primary layer, which may be a polysilicon layer, has a critical dimension specification. The lower layer is over the polysilicon layer, and is subsequently hard mask trimmed to satisfy the critical dimension specification of the primary layer. The upper layer is over the lower layer, and has a high-etching selectivity as compared to the lower layer. The upper layer substantially prevents thickness loss of the lower layer during hard mask trimming. Each of the upper layer and the lower layer may be Si₃N₄, SiON, or SiO₂. Additionally, the upper layer may be polysilicon.

Embodiments of the invention provide for advantages over the prior art. Significantly, a thick hard mask is not needed to achieve a narrow critical dimension specification of the primary layer. Rather, a thin lower layer and a thin upper layer are used. This means that the process window for photolithography and other semiconductor processes is not reduced. Furthermore, the hard mask trimming of the invention can be used for shallow trench isolation and poly gate etching, where the trench or gate has ultra-narrow critical dimensions. Other advantages, embodiments, and aspects of the invention will become apparent by reading the detailed description that follows, and by referencing the attached drawings.

### BRIEF DESCRIPTION OF THE DRAWINGS

FIG. 1 is a diagram showing an example process window for semiconductor fabrication.

FIG. 2 is a diagram showing the upper layer and the lower layer of a hard mask layer according to an embodiment of the invention.

FIG. 3 is a flowchart of a method to at least in part fabricate a feature of a semiconductor device, according to an embodiment of the invention.

FIGS. 4A-4F are diagrams showing illustratively the performance of the method of FIG. 3 for shallow trench isolation (STI) purposes, according to an embodiment of the invention.

FIGS. 5A-5G are diagrams showing illustratively the performance of the method of FIG. 3 for formation of a gate, such as a narrow or an ultra-narrow gat e, according to an embodiment of the invention.

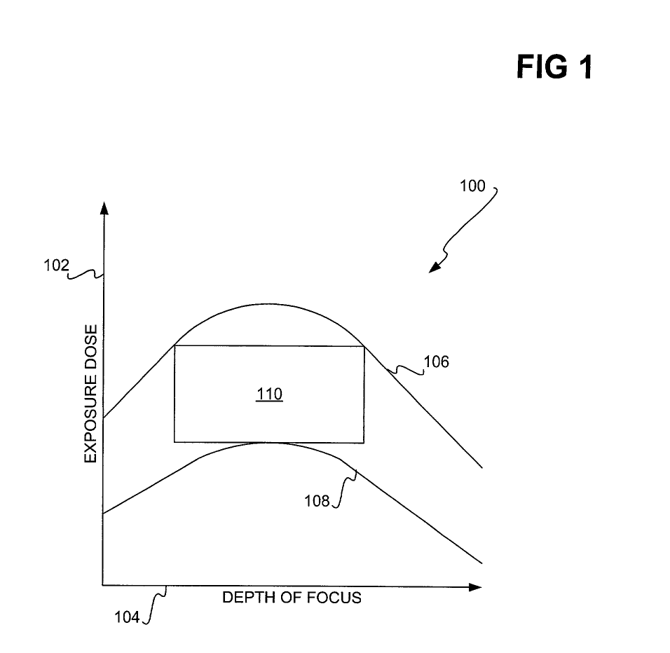

### DETAILED DESCRIPTION OF THE INVENTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

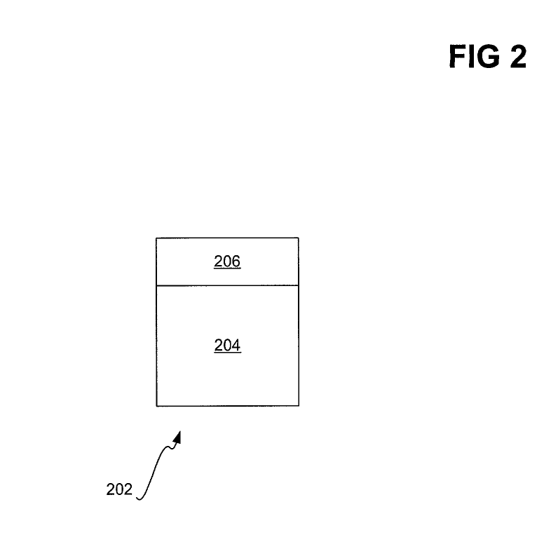

FIG. 2 shows a hard mask layer 202 according to an embodiment of the invention. The hard mask layer 202 includes a lower layer 204 and an upper layer 206. Each of the lower layer 204 and the upper layer 206 may be a dielectric film. The lower layer 204 is hard mask trimmed to satisfy the critical dimension (CD) specification of an underlying polysilicon or other type of silicon layer, not shown in FIG. 2. The upper layer 206 has a high-etching selectivity as compared to the lower layer, and substantially prevents loss of thickness of the lower layer 204 during hard mask trimming. The lower layer 204 may be Si₃N₄, SiON, SiO₂, or another material. Similarly, the upper layer 206 may be polysilicon, Si₃N₄, SiON, SiO₂, or another material. The hard mask layer 202 is part of a semiconductor device fabricated on a semiconductor wafer during the fabrication process.

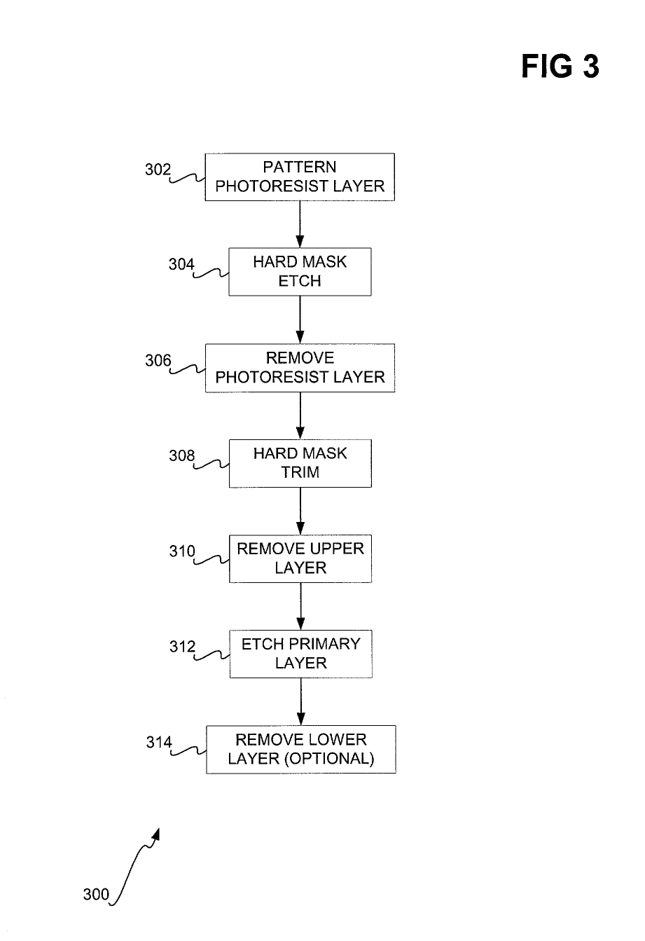

FIG. 3 shows a method 300 for at least in part fabricating a semiconductor device, according to an embodiment of the invention. The semiconductor device includes a transistor gate, a shallow trench isolation feature (STI), or another feature that is fabricated by the method 300. First, a photoresist layer on a semiconductor wafer is patterned (302). The photoresist layer is over a polysilicon layer that is generally a primary layer, and may also be another type of silicon layer or other layer. There is also a lower layer over the polysilicon layer, such as the lower layer 204 of FIG. 2, and an upper layer over the lower layer, such as the upper layer 206 of FIG. 2. The photoresist layer is over the upper layer, and optionally there is a thin pad or gate oxide layer between the lower layer and the primary layer. The photoresist layer is patterned by using a photolithographic or other process.

Next, hard mask etching is accomplished through the lower layer and the upper layer (304), and the photoresist layer is removed (306). At least the lower layer is hard mask trimmed (308), to satisfy the CD specification of the polysilicon layer. The upper layer during hard mask trimming at least substantially prevents the lower layer from losing its thickness. The hard mask trimming may be accomplished by wet etching or isotropic dry etching, with high selectivity to the upper layer. The upper layer is then removed (310). The polysilicon layer, with the lower layer still thereover, is etched (312). This etching can be performed to form a gate within the polysilicon layer, for shallow trench isolation (STI) purposes, or for another reason. In the specific case of gate formation, the lower layer is finally removed (314), although this is optional for other purposes, such as for STI purposes.

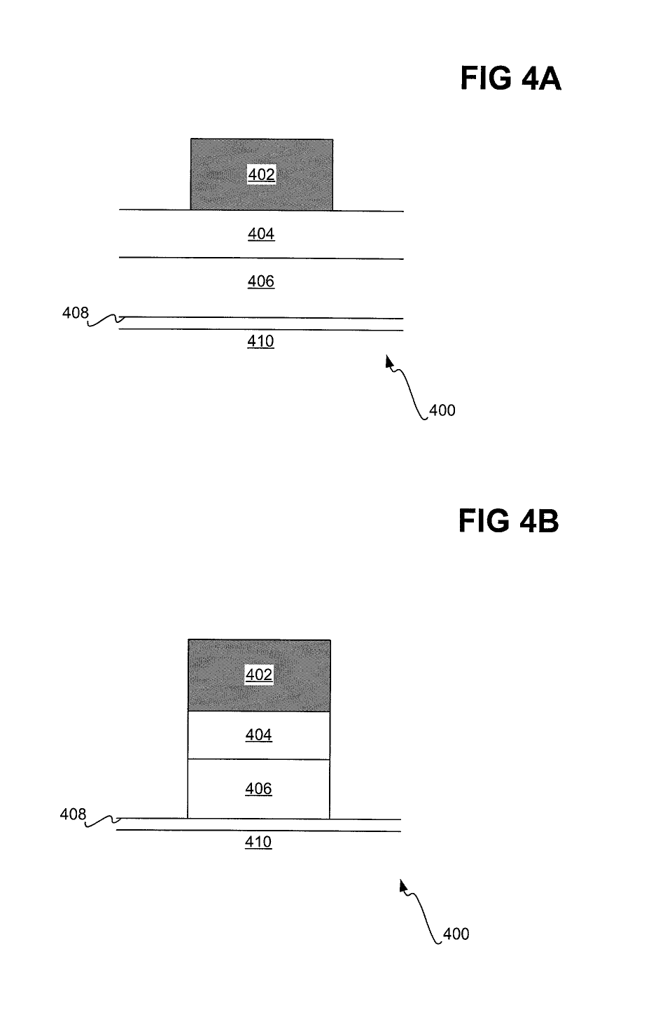

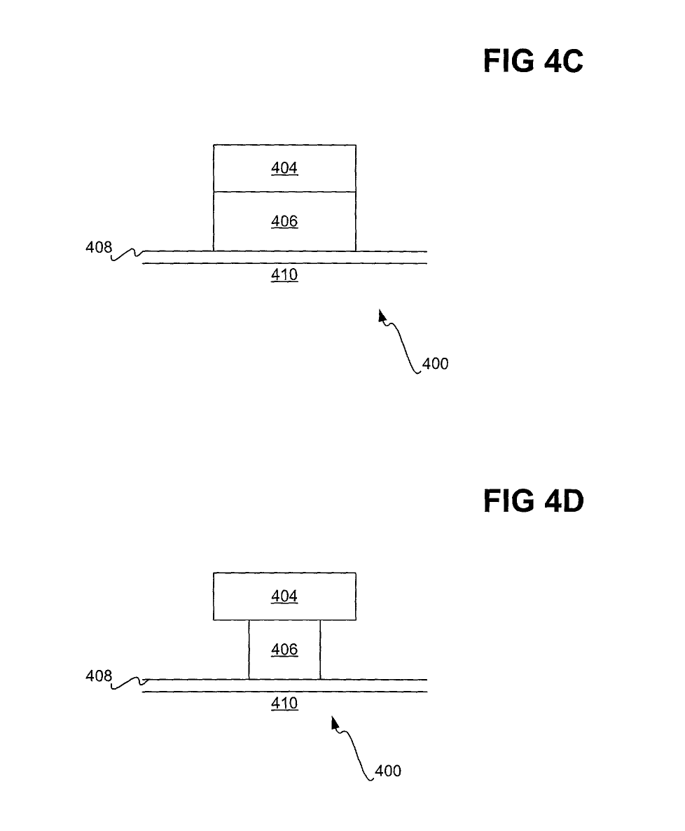

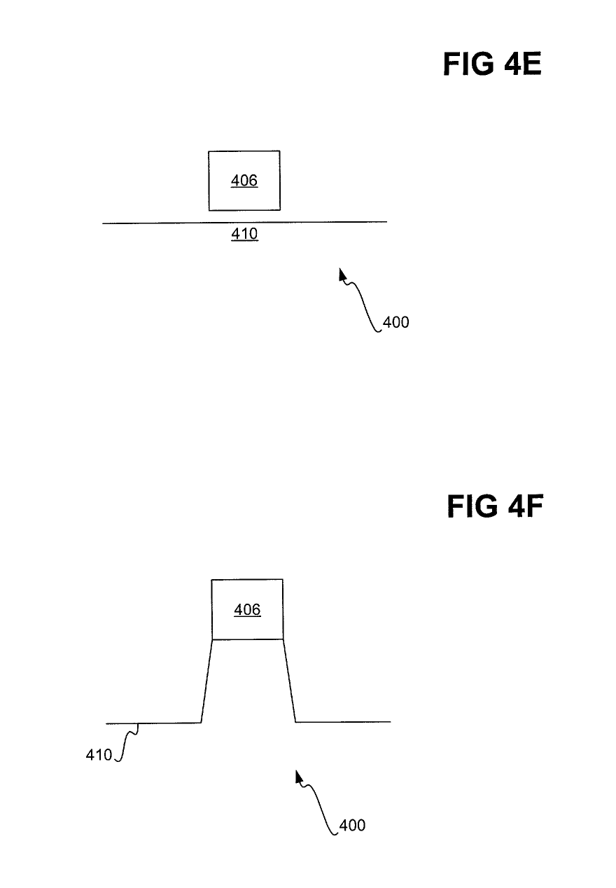

FIGS. 4A-4F illustrate the performance of the method 300 of FIG. 3 for STI purposes. In FIG. 4A, a photoresist layer 402 is over an upper layer 404, which is over a lower layer 406. The lower layer 406 is over a pad oxide layer 408, which is over a silicon layer 410. The silicon layer 410 is the primary layer. The silicon wafer is not otherwise depicted in FIG. 4A. The photoresist layer 402 has been patterned, such that it has a smaller width as compared to the layers 404, 406, 408, and 410. This results from performance of 302 of FIG. 3. In FIG. 4B, the upper layer 404 and the lower layer 406 are hard mask etched. This causes the width of the upper layer 404 and the lower layer 406 to be substantially equal to that of the photoresist layer 402. This results from performing 304 of FIG. 3. The oxide layer 408 acts as an etch stop, so that etching does not reach the silicon layer 410.

The photoresist layer 402 is then removed, by performing 306 of FIG. 3, resulting in FIG. 4C. Next, as shown in FIG. 4D, the lower layer 406 is laterally hard mask trimmed, but not the upper layer 404, resulting from performance of 308 of FIG. 3. The upper layer 404, however, prevents the lower layer 406 from losing any thickness, or height. Thus, the lower layer 406 has a width substantially less than the upper layer 404, but retains its height. The hard mask trimming can in one embodiment cause removal of substantially fifty nanometers (nm) of width of the lower layer 406, resulting in the lower layer 406 having a width of substantially five-hundred nm. The upper layer 404 is then removed, as shown in FIG. 4E, which results from performing 310 of FIG. 3. This process also removes the oxide layer 408. Finally, in FIG. 4F, the silicon layer 410 is etched, causing the formation of a trench in this layer, and which results from performing 312 of FIG. 3.

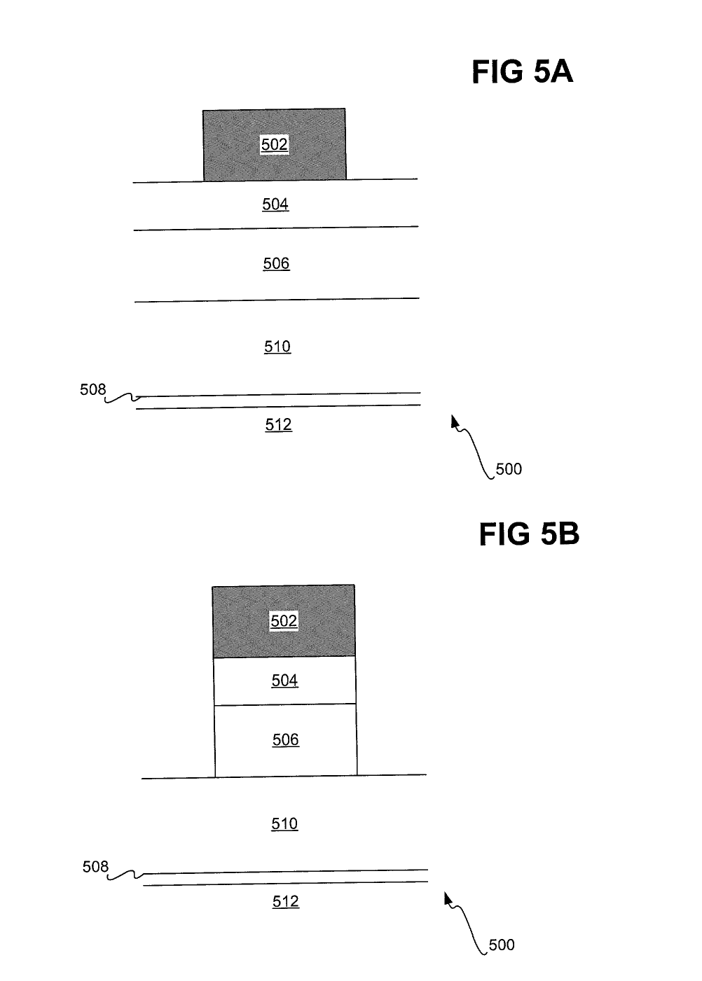

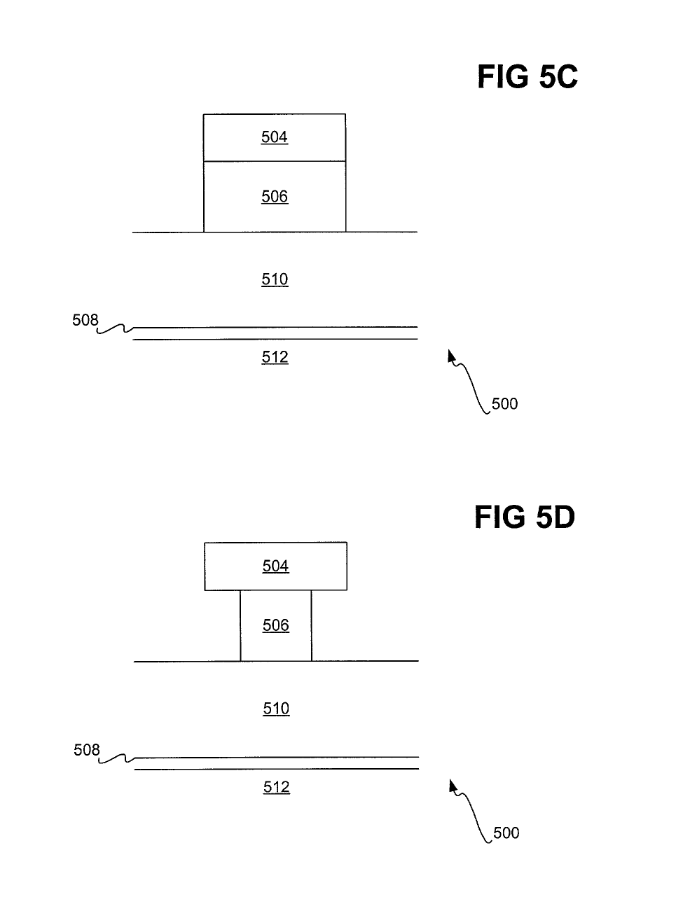

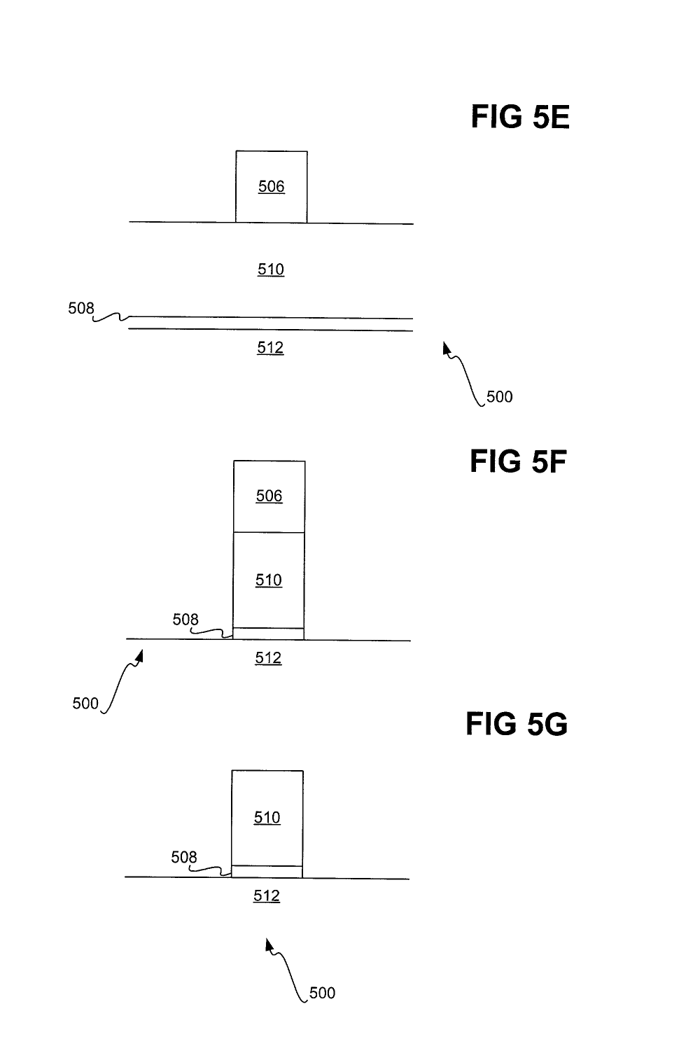

FIGS. 5A-5G illustrate the performance of the method 300 of FIG. 3 for forming a narrow or ultra-narrow polysilicon gate. In FIG. 5A, a photoresist layer 502 is over an upper layer 504, which is over a lower layer 506. The lower layer 506 is over a polysilicon layer 510, which is the primary layer. The polysilicon layer 510 is over a gate oxide layer 508, which is over a silicon layer 512. The silicon wafer is not otherwise depicted in FIG. 5A. The photoresist layer 502 has been patterned, such that it has a smaller width as compared to the layers 504, 506, 508, 510, and 512. This results from performance of 302 of FIG. 3. In FIG. 5B, the upper layer 504 and the lower layer 506 are hard mask etched. This causes the width of the upper layer 504 and the lower layer 506 to be substantially equal to that of the photoresist layer 502. This results from performing 304 of FIG. 3. The polysilicon layer 510 acts as an etch stop. The photoresist layer 502 is then removed, by performing 306 of FIG. 3, resulting in FIG. 5C.

Next, as shown in FIG. 5D, the lower layer 506 is laterally hard mask trimmed, but not the upper layer 504, resulting from performance of 308 of FIG. 3. The upper layer 504, however, prevents the lower layer 506 from losing any thickness, or height. Thus, the lower layer 506 has a width substantially less than the upper layer 504, but retains its height. The hard mask trimming can in one embodiment cause removal of substantially fifty nanometers (nm) of width of the lower layer 506, resulting in the lower layer 506 having a width of substantially five-hundred nm. The upper layer 504 is then removed, as shown in FIG. 5E, which results from performing 310 of FIG. 3. In FIG. 5F, the polysilicon layer 510 and the gate oxide layer 508 are etched, causing the formation of a polysilicon gate, and which results from performing 312 of FIG. 3. Finally, the lower layer 506 is removed, as shown in FIG. 5G.

It is noted that, although specific embodiments have been illustrated and described herein, it will be appreciated by those of ordinary skill in the art that any arrangement is calculated to achieve the same purpose may be substituted for the specific embodiments shown. This application is intended to cover any adaptations or variations of the present invention. Therefore, it is manifestly intended that this invention be limited only by the claims and equivalents thereof.

What is claimed is:

1. A semiconductor device where during fabrication the semiconductor device comprises:
a primary layer having a critical dimension specification;
a lower layer over the primary layer, the lower layer subsequently hard mask trimmed to satisfy the critical dimension specification of the primary layer; and
an upper layer over the lower layer, the upper layer having a high-etching selectivity as compared to the lower layer, the upper layer substantially preventing thickness loss of the lower layer during hard mask trimming.

2. The semiconductor device of claim 1, further comprising a thin oxide layer between the lower layer and the primary layer.

3. The semiconductor device of claim 1, wherein the primary layer comprises one of a silicon layer and a polysilicon layer.

4. The semiconductor device of claim 1, wherein the lower layer comprises a dielectric film.

5. The semiconductor device of claim 1, wherein the upper layer comprises a dielectric film.

6. The semiconductor device of claim 1, wherein the lower layer is selected from a group essentially consisting of: Si₃N₄, SiON, and SiO₂.

7. The semiconductor device of claim 1, wherein the upper layer is selected from a group essentially consisting of: polysilicon, Si₃N₄, SiON, and SiO₂.

8. A method for forming a semiconductor device comprising:
patterning a photoresist layer of a semiconductor wafer also having an upper layer under the photoresist layer and over a lower layer, and a primary layer under the lower layer, the primary layer having a critical dimension specification, the upper layer having a high-etching selectivity as compared to the lower layer;
hard mask etching the lower layer and the upper layer;
hard mask trimming at least the lower layer, the lower layer hard mask trimmed to satisfy the critical dimension specification of the primary layer, the upper layer substantially preventing thickness loss of the lower layer during hard mask trimming; and
removing the upper layer.

9. The method of claim 8, further comprising removing the photoresist layer after hard mask etching and before hard mask trimming.

10. The method of claim 8, further comprising etching the primary layer for shallow trench isolation.

11. The method of claim 8, further comprising:
etching the primary layer for gate formation; and
removing the lower layer.

12. The method of claim 8, the semiconductor wafer also having a thin oxide layer between the lower layer and the primary layer.

13. The method of claim 8, wherein the primary layer comprises one of a silicon layer and a polysilicon layer.

14. The method of claim 8, wherein each of the lower layer and the upper layer comprises a dielectric film.

15. The method of claim 8, wherein the lower layer is selected from a group essentially consisting of: Si₃N₄, SiON, and SiO₂.

16. The method of claim 8, wherein the upper layer is selected from a group essentially consisting of: polysilicon, Si₃N₄, SiON, and SiO₂.

17. A semiconductor device formed at least in part by a method comprising:
patterning a photoresist layer of a semiconductor wafer also having an upper layer under the photoresist layer and over a lower layer, and a primary layer under the lower layer, the primary layer having a critical dimension specification, the upper layer having a high-etching selectivity as compared to the lower layer;
hard mask etching the lower layer and the upper layer;
removing the photoresist layer;
hard mask trimming at least the lower layer, the lower layer hard mask trimmed to satisfy the critical dimension specification of the primary layer, the upper layer substantially preventing thickness loss of the lower layer during hard mask trimming;
removing the upper layer; and
performing one or more actions selected from the group essentially consisting of:
etching the primary layer for shallow trench isolation; and
etching the primary layer for gate formation and removing the lower layer.

18. The semiconductor device of claim 17, the semiconductor wafer also having a thin oxide layer between the lower layer and the primary layer.

19. The semiconductor device of claim 17, wherein each of the lower layer and the upper layer comprises a dielectric film.

20. The semiconductor device of claim 17, wherein each of the lower layer and the upper layer is selected from a group essentially consisting of: Si₃N₄, SiON, and SiO₂.
